(19) United States
(12) Patent Application Publication
(10) Pub. No.: US 2010/0133424 A1
(43) Pub. Date: Jun. 3, 2010

(54) ELECTRO-OPTICAL SENSORS

(76) Inventor: Norman Matheson Lindsay, Buckinghamshire (GB)

Correspondence Address: DAVIS & BUJOLD, P.L.L.C., 112 PLEASANT STREET, CONCORD, NH, 03301, US

(21) Appl. No.: 12/601,832

(22) PCT Filed: May 23, 2008
(86) PCT No.: PCT/GB08/01765

§ 371 Date: Nov. 25, 2009

(30) Foreign Application Priority Data
May 26, 2007 (GB) 0710129.8
Jun. 29, 2007 (GB) 0712687.3
Oct. 3, 2007 (GB) 0719334.5
Feb. 2, 2008 (GB) 0801958.0

(51) Int. Cl. G01J 1/04; H01L 31/0232

(52) U.S. Cl. 250/237 R

(57) ABSTRACT

An electro-optical sensor for use with a retro-reflective target (10). The light-emitting assembly involves a LED (4) and collimating and parallel lenses (2, 4), and the sensing assembly involves a collecting lens (5), an aperture plate (6) and a photodiode array (7) with optional field-curvature correcting lens (8). The lens (5) abut the substrate (1) within the aperture of plate (6) so that the entrance pupil and the exit pupil, when viewed from the target (10), abut opposite, parallel straight-edges of the substrate (1). The photodiode array (7) may be a linear pixel array parallel to the substrate-surface, or may be replaced by a single, large-area photodiode with aperture-limitation of its field of view to a narrow fan-shape parallel to the substrate-surface. A plurality of light-emitters (77) may be used with photo-detectors (71) that have individual light-collection optics (72, 73) with merged fields of view. The sensor can sense golf club-head (100) movement and vehicle speed and plate number (116).

This application is a National Stage completion of PCT/GB2008/001765 filed May 23, 2008, which claims priority from Great Britain patent application no. 0710129.8 filed May 26, 2007.

### FIELD OF THE INVENTION

This invention relates to electro-optical sensors for use in the sensing of retro-reflective targets.

### SUMMARY OF THE INVENTION

According to the present invention there is provided an electro-optical sensor comprising a light-emitter having co-acting light-projection optics for projecting a light beam from the light-emitter to illuminate a retro-reflective target at a location spaced from the sensor, and a photoelectric detector having co-acting light-collection optics, the photoelectric detector with its light-collection optics being located side by side with the light-emitter and its light-projection optics either side of an intervening light-screen, and wherein the light-collection optics focuses onto the photoelectric detector light of the light beam reflected retro-reflectively from the spaced target-location, wherein the exit pupil of the light-projection optics and the entrance pupil of the light-collection optics viewed from the target-location abut opposite parallel straight-edges of the light-screen as viewed from that location.

The exit pupil represents the aperture through which all light-emitter rays pass, as viewed from a given point of the target-location. Typically, the light-emitter is an LED (light emitting device), and the exit pupil is not usually in these circumstances formed by a separate light-stop aperture but instead by the image of the LED as is seen at the target-location (for convenience reference to an LED refers to its active light-emitting surface as distinct from its physical component package). However, since the LED light rays are typically focussed into a narrow or flat exit light beam, the image of the LED as seen at the target is typically limited in at least one direction by the rim of a projector lens; the rim may be a flat edge that abuts the light-screen. The object-space of the light-projection optics is within the sensor with the LED as the object; the image-space is outside the sensor and the image is usually real and formed at or near the target-location. However, in some implementations the image of the LED can be at some other distance (including infinity) and can be real or virtual. The entrance pupil represents the aperture through which all rays incident on the photoelectric detector pass, as viewed at a given point from the target-location, and in this respect may be: an aperture in front of the light-collection optics, the image of an aperture as seen at the target-location through the light-collection optics; a combination of both the above of these; or the rim of a lens at the front of the light-collection optics. The aperture is typically formed by a notch on one straight edge of a light-block plate that abuts the light-screen. The object-space for the light-collection optics is outside the sensor and the object is a reflecting surface at the target-location; the image-space is inside the sensor and the image is real and ideally formed on the light sensitive surface of the photoelectric detector.

The light-collection optics may be eccentric such that the centre of the entrance pupil of the light-collection optics is located between the optical axis of the light-collection optics and the light-screen. Preferably, the entrance pupil of the light-collection optics extends to less than 50% of the spacing of the optical axis of the light-collection optics from the light-screen. This is especially required for implementations where the height of the photoelectric detector from the light-screen is greater than the corresponding height of the entrance pupil. It is thus common in sensors according to the invention that at least one lens of the light-collection optics does not physically occupy the space containing its optical axis but is limited to a small marginal segment of lens bounded on one side by a flat edge that abuts the light-screen. The light-projection optics may also be eccentric, particularly where a small exit pupil is required.

The sensor signal amplitude is proportional to the light power or the light energy incident on the photoelectric detector (depending on whether the detector is non-integrating or integrating respectively) for light wavelengths within the spectral response region of the photoelectric detector. The amount of light reflected by the target and focussed onto the photoelectric detector can be increased by enlarging the exit pupil and enlarging the entrance pupil. Thus, all other factors being equal, doubling the area of both pupils will quadruple the signal response. In general, sensor signal amplitude increases as the product of the area of the exit pupil and the area of the entrance pupil, but limits rapidly as the observation angle increases. This product is a maximum when the areas of exit and entry pupils are equal (for a given overall combined area determined by maximum useful observation angle). However, maximising available signal is often not a prime objective provided that signal-to-noise is satisfactory. Instead, it is preferable to reduce the size of the entrance pupil compared to the exit pupil in order to improve depth of focus. Limiting the area of the entrance pupil also limits the amount of ambient light that reaches the photoelectric detector.

Thus, in a sensor according to the invention, it is preferable that the entrance pupil is smaller than the exit pupil. It is especially preferable that the entrance pupil is only slightly larger than the image of a pixel (where a pixel array device is used) as seen at the target-location. This ensures excellent depth of focus over a wide range. To compensate for restricted entry-pupil size, the exit pupil for light emission from the LED of other light-emitter should be as large as practical but not so as to increase observation angle above a useful limit.

A very small entrance pupil (as obtains in a pin-hole camera) provides effectively infinite depth of focus, but a more preferable size of entrance pupil is one that is matched to, or only slightly bigger than the object-spot size on the target corresponding to the minimum spot size that must be resolved in the photoelectric detector (e.g. a pixel size). Preferably, the dimensions (height and width) of the entrance pupil of the light-collection optics are the same as or up to twice the corresponding dimensions of a pixel of the photoelectric detector as viewed from the target-location in the entrance pupil of the light-collection optics.

The purpose of the light-collection optics is to ensure that the photoelectric detector is receptive only to light rays within a very narrow field of view (herein called the ‘detection field’) that is substantially parallel to the light-screen. The detection field may be a narrow pencil that is sensitive to a small spot on the target, but more usually the detection field is fan shaped, and sensitive to light reflections along a line segment of the target, where the line segment is substantially coplanar with the light-screen.

The purpose of the light-projection is to provide an exit light beam that envelops the detection field at the target-location but is also collimated so as to optimise incident light intensity. The exit light beam is thus a pencil beam or a fan beam substantially parallel to the light-screen.

The photoelectric detector may be a single, a dual or a quadrant photodiode, a position sensitive detector (PSD), a linear pixel array or any other configuration of photoelectric elements as required for different applications. In one preferred embodiment, the photoelectric detector is elongate with its major light sensitive axis parallel to the substrate. Preferably, the photoelectric detector is positioned at, or very close to, the image plane of the light-collection optics that corresponds to an object plane containing the target-location. Thus, a spot on the target (an ‘object-spot’) focuses onto a very small ‘image-spot’ along the light sensitive axis of the photoelectric detector. The position of the image-spot along the light sensitive axis corresponds to the position of the object-spot on the target. In general, the position of the image-spot is proportional to an angle θ subtended by the corresponding object-spot relative to the centre-axis of the sensor, as measured in the plane of the light-screen. In one form of the invention, the elongate sensor is a linear pixel array and a measurement of θ is found from the pixel positions in the array.

One of the objects of the present invention is to minimize the sensor observation angles so as to enhance detection of retro-reflections relative to other modes of reflection. The observation angle is defined as the angle subtended at the target between a first ray within the exit light beam and a second ray within the detection field of view that is a reflection of the first ray. The observation angle varies depending on where the said first ray exits the exit pupil and where the said second ray enters the entrance pupil.

Preferably, light-stop apertures, or the equivalent, limit the maximum observation angle σ_{MAX} to not more than 5 degrees or not more than 0.5 degree or less, dependent on the characteristics of the retro-reflector to be sensed.

The minimum observation angle is determined by the extent that the light screen screens part of the exit aperture and/or part of the entrance aperture as viewed at the target. For a light-screen of thickness T and a target range distance of R (measured from the outer edge of the light-screen to the target surface), the minimum possible observation angle is T/R radians but this minimum can only be achieved if the optics are very accurately aligned. In general the minimum observation angle σ_{MIN} is arctan[(T+δ)/R] degrees, where δ is a function of alignment errors. In general, δ is dependent on θ, the angle subtended between an incoming reflected ray and the optical centre-line. Preferably σ_{MIN} is less than 0.2 degree and more preferably less than 0.05 degree for all values of θ within a detection field of view.

To ensure that δ is insensitive to misalignment, it is preferable that the position of the entrance and exit pupil behind the outer edge of the substrate is less than 60T.

The target may have retro-reflective surface that is continuous or separated and may be curved or flat. Retro-reflective surfaces may be provided on at least two surfaces at different distances from the sensor and comprise a plurality of separate retro-reflecting elements. The range R is then measured from the side of the light-screen nearest the target to the furthermost surface of the target.

Use may be made of the electro-optical sensor of the invention to detect a non-reflecting object that blocks reflected light from a background retro-reflector at range R. This non-reflecting object may be interposed at variable distances between the sensor and the background retro-reflector. Preferably, the light-collection optics is focussed such that objects at range R form a real image on or very close to the light sensitive surface of the photoelectric detector.

The electro-optical sensor of the invention may involve only one light-emitter and one photoelectric detector. Alternatively, one light-emitter is used in conjunction with two or more photoelectric detectors and co-acting light-collection optics. As a further alternative, a plurality of light-emitters may be used that have individually co-acting light-projection optics for projecting a plurality of light beams that merge with one another, and in these circumstances, there may also be provided a corresponding plurality of photoelectric detectors having individually co-acting light-collection optics with fields of view that merge with one another.

The light-screen of the electro-optical sensor of the invention may provide a flat, mechanically stable surface or substrate on which the components of one or more sensors may be mounted. Several photoelectric detectors and light-emitters with their co-acting optics may be directly mounted in correct angular relationship with one another on such a substrate to form one sensor assembly having an overall wide-angle detection field of view. Distributing several sensors in this manner reduces the field of view required of individual photoelectric detectors, allowing the use of smaller, cheaper and faster electro-optical sensing, simplification of the design and form of the light-collection and -projection optics, and allows for enhanced optical gain. The distributed light emitters allow much higher light-output power to be used than is permitted from a single source under safety regulation limits (for example, Class 1M limits).

One important application of the present invention is edge detection of straight-edged patterns on a target using linear pixel photoelectric detectors. The position of the edge of a retro-reflector can be resolved within a small fraction of a pixel using grayscale measurements. As a moving retro-reflective edge crosses into the field of view of a given pixel in a linear array, the signal output magnitude changes from a minimum to a maximum in proportion to the amount of retro-reflected light collected and focused onto that pixel.

In order that the instantaneous position of a straight retro-reflective edge is accurately determined, two prerequisite conditions should be met. Firstly, the retro-reflectivity should be substantially uniform along the straight edge. It has been found that despite its relatively lower coefficient of retro-reflection, glass-bead type retro-reflective material is often preferable to prismatic material because it provides more uniform reflection. Secondly, the sensitivity of the sensor should be reasonably constant across all pixels and free from abrupt changes.

One factor that can adversely affect the uniformity of the sensor sensitivity is abrupt change in the exit beam output power at different values of 8 that occur when two or more light beams are merged. Preferably, when two or more exit beams are merged, the light intensity fall-off characteristic at overlapping edges of adjacent beams should be gradual and the beams aligned such that the power intensity changes gradually throughout the composite beam. Several beams may be used to create a ‘shaped radiation pattern’ wherein the light intensity is varied to compensate for loss of sensor sensitivity at different values of a Preferably, the incremental beam intensity should not vary by more than 10% for an increment corresponding to one pixel in the detection field but more preferably it should not change by more than 1%.

In one form of the electro-optical sensor of the invention, the light-projection optics comprises a cylindrical or other form of anamorphic lens with positive power in the meridional plane perpendicular to the substrate or other light-screen, and zero power in the meridional plane parallel to the substrate or other light-screen so as to focus a portion of the total light emitted from the LED into a fan beam parallel to the light-screen with very small divergence normal to it. For convenience, this lens is referred to as herein as the ‘collimating lens’.

The fan beam formed by the collimating lens appears at the target-location to emanate from an elongated source with its major axis normal to the light-screen and coincident with the centre of, for example, the light-emitting LED. The elongated source is produced as a consequence of the lens forming an image of the LED at or near the target that is highly magnified in a direction normal to the substrate but not magnified parallel to the substrate. This image of the LED forms the exit pupil for the fan beam. The width of the exit pupil is equal to the width of the LED and, in the absence of any limiting stop, the height of the exit pupil is equal to the height of the collimating lens. The edge of the collimating lens adjacent to the substrate or other light-screen is flat and abuts the light-screen. This arrangement ensures that the exit pupil abuts the light-screen.

In another form of an electro-optical sensor of the invention, a second projector lens is provided with positive power in the meridional plane parallel to the light-screen. The second projector lens is used to alter the position of the exit pupil and, optionally, the angular width of the exit beam in the plane parallel to the light-screen. For convenience, this lens, which is referred to herein as the ‘parallel’ lens, forms a real or imaginary image of the LED and thereby shifts the position of the elongated source in front of or behind the LED respectively. This is especially useful in ensuring that the elongated source is positioned along the optic axis so as to coincide with the entrance pupil of the light-collection optics. This in turn minimises observation angles and ensures optimum retro-reflection performance.

In one preferred embodiment, the parallel lens has zero power in the meridional plane normal to the light-screen (with positive power in the parallel plane) and provides a real and preferably magnified image of the LED near the outer edge of the light-screen. The exit pupil is the image of the LED as seen at the target through both the collimating lens and the parallel lens. This arrangement allows a long focal length in the collimating lens, which desirably allows lower magnification for a given range R. The magnification of the LED parallel to the light-screen also increases the width of the exit pupil and increases the optical gain of the system. The parallel lens can provide correction for the loss of light output intensity at the angular extremities of the fan beam.

Non-imaging optics such as a compound parabolic concentrator or a gradient index

(GRIN) optic may be used instead of linear imaging lenses. These alternative devices may improve ease of the system assembly and alignment, but cannot improve optical gain since the optical invariant is independent of the emitted beam-forming means and can only be increased by using a source with greater radiant intensity and/or increasing the exit pupil. However, the exit pupil is preferably limited to a size that keeps the maximum observation angle σ_{MAX} to not more than 5 degrees or preferably less, since larger exit pupils contribute very little to the retro-reflective gain of the system but increase the likelihood of the sensor receiving unwanted spectral reflections.

In electro-optical sensors according to the invention, there is no internal light path that allows cross-coupling of light from the light emitter to reach the photoelectric detector. Cross-coupling in arrangements of prior art, disadvantageously increases photocurrent and thereby increases shot noise in the detector. Preferably, the light-screen and sensor housing are electrically conductive so as to provide high electrical shielding between light emitter circuits and photoelectric detector circuits within the sensor. This is particularly valuable if pulsed operation of the light-emitter is required.

### BRIEF DESCRIPTION OF THE DRAWINGS

Electro-optical sensors in accordance with the present invention will now be described, by way of example, with reference to the accompanying drawings, in which:

FIGS. 1a, 1b and 1c are schematic diagrams of an electro-optical sensor according to the invention, the sensor being represented in side elevation in FIG. 1a, in plan from below in FIG. 1b and in plan from above in FIG. 1c;

FIG. 2 is a representation of the light pattern projected by an LED;

FIGS. 3a, 3b and 3c are schematic diagrams illustrative of features to be described of an electro-optical sensor according to the invention;

FIG. 4 shows a variant of the electro-optical sensor of FIG. 3a involving a non-uniform substrate and an optimised depth of focus;

FIG. 5 is a schematic diagram of light-collection optics of an electro-optical sensor according to the invention, where the entrance pupil is provided by a light-stop aperture behind the collector lens of the light-collection optics;

FIG. 6 is a schematic diagram of light-collection optics of an electro-optical sensor according to the invention, where the entrance pupil is provided by a light-stop aperture in front of the collector lens of the light-collection optics;

FIGS. 7a and 7b are schematic diagrams illustrative of an electro-optical sensor according to the invention where four separate light emitters and co-acting light detectors are carried by a common substrate;

FIG. 8 is a schematic diagram of a prior art beam-forming arrangement that combines the outputs of four separate LEDs;

FIGS. 9a and 9b are polar diagrams showing how the radiation patterns of the four separate light emitters of FIG. 7b are combined;

FIGS. 10a and 10b are, respectively, toe-end and impact-face views of a golf club-head which has a retro-reflective shaft attachment and which is for use with an electro-optical sensor according to the invention; and

FIG. 11 is a schematic diagram illustrating a method of measuring the speed of a moving vehicle and reading alpha-numeric characters from the vehicle's registration plate, using electro-optical sensors according to the invention.

### DETAILED DESCRIPTION OF THE INVENTION

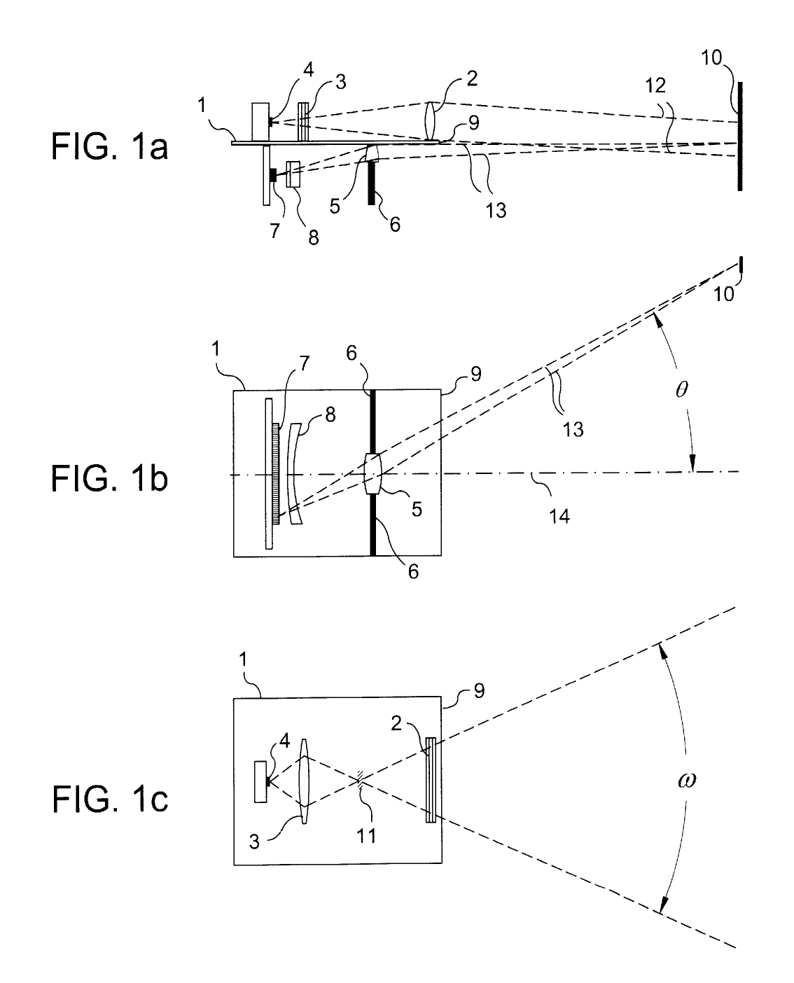

Referring to FIGS. 1a, 1b and 1c, the electro-optical sensor shown has a substrate 1 that separates a light-emitting assembly from a light-sensing assembly that are mounted on opposite sides of the substrate 1, and provides a light-screen between them. The light-emitting assembly in this case comprises a collimating lens 2, a parallel lens 3 and a light-emitting device in the form of an LED 4, whereas the light-sensing assembly comprises a collector lens 5, an aperture plate 6, a photodiode array 7 and (optionally) a field-curvature correcting lens 8. The lens 5, which has a rectangular rim, is located within the aperture of the plate 6 with one of its edges abutting the substrate 1 and the other three bounded by the aperture plate 6. In this way, the lens 5 provides the entrance pupil of the sensor since all light-rays incident on the photodiode array 7 pass through the lens.

The substrate 1 is opaque and has thickness T, where Tis very small compared with the operating range R. The operating range R is the distance between the front end 9 of the substrate and a retro-reflective object or target 10 that is to be detected by the sensor. Typically R is in the range 50T to 5000T or greater. Preferably, the substrate 1 also provides good electromagnetic shielding between the light-emitting and the light-sensing assemblies.

The LED 4 is preferably a high-power light-emitting device with small active area such as one of the high-power infrared emitters sold under the Registered Trade Mark OSRAM as types SFH4230 and SFH4231. These devices emit at high power (e.g. up to 1000 mW continuous from type SFH4231) and have an active area of one millimetre square. The parallel lens 3 is typically a cylindrical lens that forms a real image of the LED 4 at location 11 (shown in FIG. 1c). In the plane parallel to the substrate 1, the image at location 11 is a magnified image of the LED 4, but the image space beam divergence w is proportionally reduced relative to the object-space beam divergence such that the output-beam light-intensity, measured in units of power per steradian, is increased. The position of the image location 11 is arranged to be immediately opposite the entrance pupil that is provided by the lens 5 on the reverse side of the substrate 1. Thus, the emitted and received light rays emanate from and return to a common narrow region with axis passing through lens 5 and image location 11, so the component of observation angle in a plane parallel to the substrate 1 has a mean value of zero. However, the component of observation angle in a plane normal to the substrate 1 is always positive and has a minimum possible value of T/R radians.

In the plane normal to the substrate 1, lens 2 focuses at least part of the light emitted by the LED 4 to form a real image at the target 10 and thus increases the radiant intensity of the fan beam 12. In the arrangement described above, lens 2 and lens 3 have different focal lengths and view the same object (namely LED 4) but, because their lens powers are in orthogonal planes, their effect on the exit-beam shape can be considered independently.

In another form of the electro-optical sensor of the invention, the parallel lens 3 can be used to form a magnified virtual image of LED 4. This also increases the radiant intensity but shifts the apparent source of light-emission to behind LED 4. With this arrangement, LED 4 must be positioned close to the collimating lens 2 in order that the virtual image is positioned opposite the entrance pupil. This in turn means that lens 2 must have a much shorter focal length.

However, it is much more preferable to have a long focal length in the collimating lens 2. The longer focal length reduces the magnification required to focus the output light at a given target range R and thus allows larger tolerance on the positioning of LED 4 relative to the focal plane. It follows from the principle of the optical invariant that the intensity on the sensed portion of the target 10 (that is, the portion of the target 10 that is focussed onto the photodiode array 7) is independent of the power of lens 2 but is dependent on its size. Thus, for a given size of lens-aperture, a stronger lens will accept a larger portion of the total output power of LED 4, but the resultant fan beam has greater divergence (which varies as the inverse of focal length) so more of the output light spreads away from the target. Moreover, it is often required to ensure that output light power from any single source is below a safety regulation limit (for example, the Class 1M limit) so excessive spreading and wasted light output is undesirable.

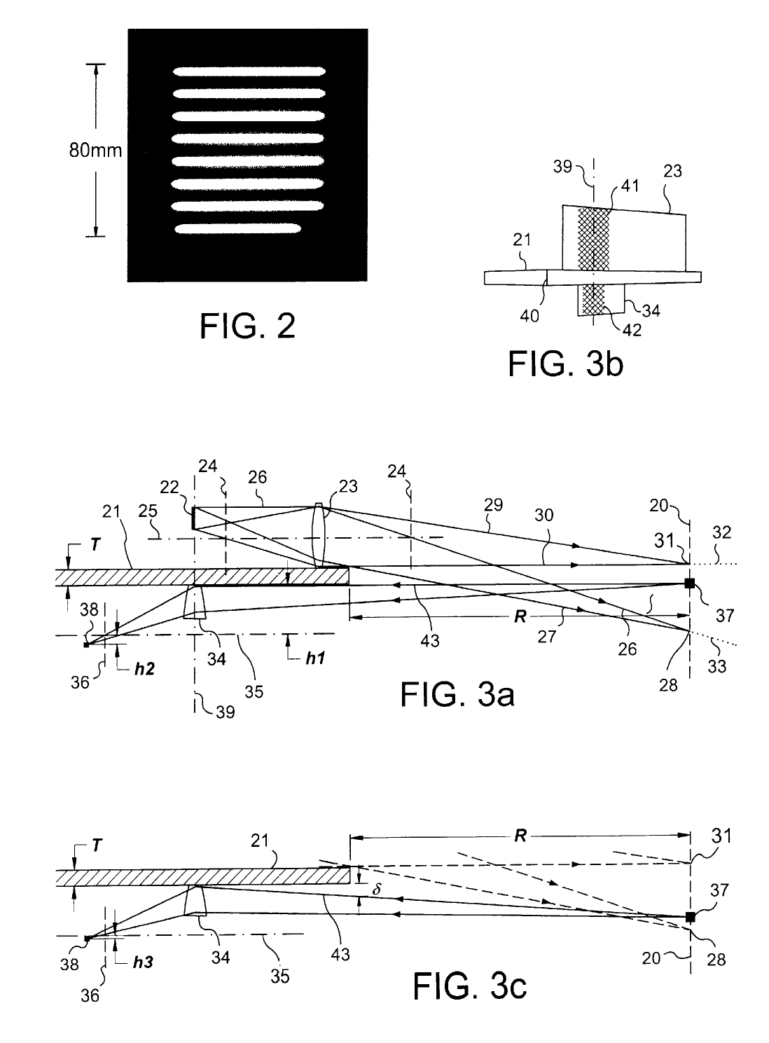

Some preferred LED devices exhibit non-uniform emission over the active emitting area. FIG. 2 shows a representation of the light pattern emitted from a visible spectrum version of the LEDs sold under the Registered Trade Mark OSRAM as types SFH4230 and SFH4231; the emitted light was projected onto a screen at a distance of 1.5 metre and magnified ×80. It is clearly seen that the light emission is not uniform but divided into eight separate strips. A high magnification optic with short focal length and wide acceptance angle could inadvertently project a low emission area (between emitting strips) onto the area of the target that is to be detected by the sensor, whereas a lower magnification optic would project a larger area of the LED with better average emission.

Most LEDs are designed with square active areas. However, in the present case, an elongate active area would be beneficial. In this respect, a modified design of LED exhibiting a single continuous strip of light over an extended length, rather than in separate strips as represented in FIG. 2, would be valuable.

The present invention relies on focussing arrangements that are non-paraxial. Instead, the most useful portion of the emitted light and nearly all the received light is concentrated in marginal rays that pass through the edge of each lens and close to the substrate 1. Only a small eccentric section of lens 5 is utilised and for some applications a similar eccentric lens arrangement can be used for lens 2. This arrangement bends light rays to accommodate for the finite size of the photosensitive device and the LED (which is typically mounted on a heat-sink) such that light rays to and from these devices (which are typically a centimetre or more apart) appear to be almost coplanar. The photodiode array 7 is positioned close to the focal plane of lens 5 such that light rays from a distant object passing through lens 5 are focussed on the photodiode. The sensor provides high retro-reflective gain conditions over a wide angular field of view ω.

Various types of optics may be employed, such as prisms, mirrors, cylindrical, sphero-cylindrical, other types of astigmatic lenses, spherical and aspheric corrected lenses. The additional field-flattener lens 8 is employed to correct for Petzval curvature, and can also correct for other aberrations in the main collector lens 5.

The light-emitting assembly and the light-sensing assembly are housed within an enclosure (not shown) that prevents light from the LED 4 propagating to the photodiode array 7 by any path other than by reflection from an external surface within the limits of the reflected rays 13 depicted by dotted lines in FIGS. 1a and 1b.

In some applications the photodiode array may be a linear pixel array, as depicted by the array 7 in FIG. 1b, with the array axis parallel to the substrate 1. This has the advantage that an angle θ can be determined, where θ is the angle subtended between an incoming reflected ray 13 and the optical centreline 14. As an alternative, the photodiode array may take the form of a single, large-area photodiode and one or more apertures are then used to limit the width of the received light rays within a narrow fan-shaped field of view parallel to the substrate 1. This arrangement senses when and wherever a retro-reflective target-marker is in the detection plane (that is, in the plane of the substrate 1 and within angle ω) but it cannot determine angle θ. The single photodiode variant has the advantage of being non-integrating with very fast response whereas the pixel array variant requires a finite light exposure time and data read-out time.

Referring now to the schematic diagram of FIG. 3a, a target-surface 20 is positioned a distance R from the edge of an opaque substrate 21 of uniform thickness T. A LED 22 and a cylindrical light projector lens 23 are arranged on one side of the substrate 21 so as to focus light from the LED 22 onto the target-surface 20. The focal planes of lens 23 are depicted by dashed lines 24 and its optical axis is depicted by ‘dot-dash’ line 25. Typically, the ratio of R to the focal length of lens 23 is very large so that the image of LED 22 formed at or near the target-surface 20 is greatly magnified at ×10 or more (for clarity of illustration though, it is shown with only ×3 magnification).

Marginal rays 26 and 27 from the upper edge of LED 22 focus at point 28 on the target-surface 20, and marginal rays 29 and 30 from the lower edge of the LED focus at point 31. In the direction normal to the plane of FIG. 3a, the light from lens 23 spreads out into a fan beam since the lens 23 has no power in that direction. The exit beam from lens 23 thus projects a strip of light onto the target-surface 20 that is elongate normal to the plane of FIG. 3a and is bounded (ideally) by lines normal to that plane, through points 28 and 31. For positions of the target-surface 20 between the LED image plane (at distance R) and the substrate 21, the exit beam is fairly well collimated but starts diverging for distance beyond R as shown by dotted lines 32 and 33.

On the underside of substrate 21, a collector lens 34 focuses light reflected from the target-surface 20 onto a linear pixel array extending normal to the plane of FIG. 3a. One edge of lens 34 is flat and coplanar with the underside of the substrate 21, and the remaining edges are surrounded by a light blocking stop (not shown). The lens 34 is offset physically from its optical axis 35 (indicated by dot-dash line) but its optical power in spite of this, is radially symmetrical about the axis 35. The focal plane of lens 34 is indicated by dashed line 36 in FIG. 3a.

Light from a small retro-reflective object-spot 37 of the target-surface 20 is focussed onto a pixel 38. The entrance pupil in FIG. 3a comprises the image of pixel 38 as seen at the target-surface 20 through lens 34. Thus, for each pixel in the linear array there is a unique entrance pupil that receives light from different parts of the target-surface 20 along a line collinear with object-spot 37 and normal to the plane of FIG. 3a. All these unique entrance pupils have a common physical position, namely, at lens 34, and with LED 22 directly opposite lens 34 on the upper side of substrate 21, it is ensured that the light source for the exit fan-beam and the light receptor are centred on a common axis (denoted by dash-dot line 39) so as to optimise the arrangement for retro-reflective gain.

FIG. 3b is a schematic view of the sensor of FIG. 3a looking from the target 20 towards the sensor in the plane of the substrate 21, but obliquely along a corner 40 of the substrate. The hatched area 41 represents the image of LED 22 as seen through lens 23 and is thus the exit pupil corresponding to a given point on the target 20. The LED image represented by area 41 extends the full height of lens 23 since this lens provides nominally infinite magnification in directions normal to the substrate 21, and its width is equal to the width of LED 22. The hatched area 42 represents the image of a pixel in the lens 34 and is thus the entrance pupil corresponding to the given point on the target 20. The exit and entrance pupils represented by the areas 41 and 42 are centred on axis 39 and abut the opposite straight edges of the intervening substrate 21; this gives optimum retro-reflection sensitivity for this arrangement of sensor.

For most common retro-reflective materials, the coefficient of reflectivity exhibits a peak at near-zero observation angles. However, near-zero observation angles can only be achieved when the exit and entrance pupils of a sensor are very small (such as pin-holes) and co-axial. This can be achieved in sensors that use beam-splitting optics to provide co-axial emitted and received light beams but practical co-axial sensors must have finite exit and entrance pupil apertures in order to emit and receive useful amounts of light energy. It is also noteworthy that practical retro-reflective materials reflect a negligible fraction of the total light along the axis of ‘zero observation angle’ but instead most of the retro-reflected light is contained in a cone spreading out a few degrees about this axis. Thus, the average magnitude of observation angles in any useful sensor device for detecting retro-reflective targets must be finite.

In sensors according to the present invention, the exit and entrance pupils are not co-axial but very closely adjacent. Although this arrangement increases the average of the observation-angle magnitudes, the fact that the exit beam is not attenuated by a beam splitter (which typically reduces output power by 50%) more than compensates in some applications. For example, the sensitivity of the electro-optical sensor of FIG. 3a is dependent on the amount of light from LED 22 that can be focussed onto the retro-reflecting spot 37 and the effective average retro-reflectivity, which is dependent on observation angle. For the same size of exit pupil (which relates directly to the size of the projector lens 23) and the same LED drive conditions, the sensor of FIG. 3a will project twice the intensity of light compared with a co-axial sensor where the exit beam passes through a beam splitter. Assuming that the entrance pupil is very small compared with the exit pupil (which is preferable), then the average observation angle will approximately double. However, for some preferred retro-reflective materials, a doubling of average observation angle from say 0.1 degree to 0.2 degree only slightly reduces the average retro-reflectivity so there is a net improvement in sensitivity. Other advantages of the configuration of FIG. 3a will become apparent from description below.

The position and orientation of the pixel array relative to the lens focal plane 36 and the optic axis 35 are critical. The optimum position is illustrated in FIG. 3a. The lens optical axis 35 is parallel to substrate 21 and offset at a height h1 from the substrate, where height is measured perpendicular to the substrate. The distance of the pixel array behind the focal plane 36 is adjusted such that a line object on the target surface is focussed on the array and forms a line image on the pixel line array. The pixel line array is parallel to the substrate 21 and offset from the optical axis 35 by height h2 where the ratio h2/h1 is equal to the ratio of image size to object size (i.e. ratio h2/h1 is equal to the demagnification). When the above conditions are met, a marginal ray 43 passes very close to the surface of the substrate 21. This ensures that the minimum observation angle is equal to arctan(T/R).

In one exemplary embodiment, the thickness T of substrate 21 is 1 millimetre, the range distance R is 3000 millimetres, the height of lens 23 is 15 millimetres and the height of lens 34 is 5 millimetres. The minimum observation angle in these circumstances is less than 0.02 degree, the maximum observation angle is 0.4 degree and the average observation angle is approximately 0.2 degree (i.e. about half the maximum observation angle). This calculation neglects the width of the exit and entrance pupils, which have a very small effect on the above values.

In FIG. 3c the height h3 of the pixel array is less than the optimum height h2. This has the effect of shifting the height of the target object-spot 37 closer to the optical axis 35 and, in turn, causes the marginal ray 43 closest to the substrate 21 to diverge away from the substrate. The minimum observation angle is now increased because the entrance pupil has moved away from the substrate by amount δ. When h3 is greater than h2, marginal ray 43 is vignetted or cut off by the substrate and in badly aligned cases the entrance pupil is totally obscured by the substrate. In general, the minimum observation angle is equal to arctan[(T+δ)/R] degree, where δ is a function of alignment errors and is dependent on the angle of view θ. To ensure that δ is insensitive to misalignment, it is preferable that the position of the entrance and exit pupil behind the outer edge of the substrate is less than 60T.

Because LED 22 is normally relatively large compared with the dimensions of a photo-detector pixel, alignment of the LED is usually tolerant of small errors.

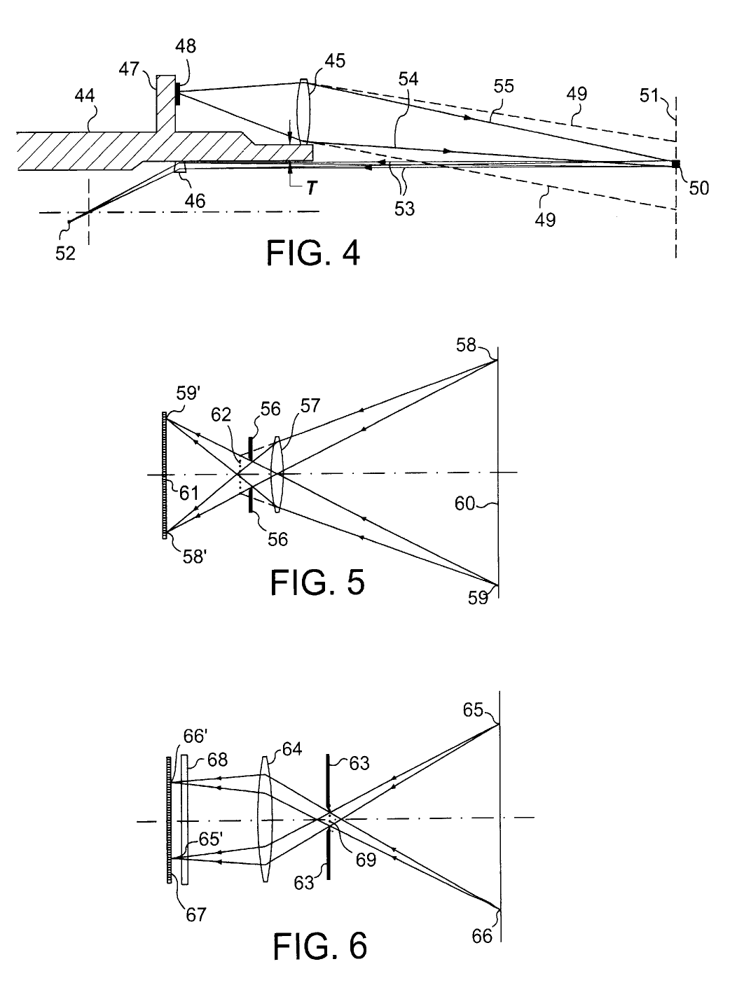

FIG. 4 shows a variant of the arrangement of FIG. 3a. Here a substrate 44 has non-uniform cross-section. However, the end portion that separates the projector lens 45 and collector lens 46 has thickness T as before, and the cross-sectional profile is such that exit and entry light rays are not vignetted by the substrate 44. Advantageously, the substrate 44 may be fabricated as a precision casting and an integral flange 47 provided to form a heat-sink for LED 48.

As before, the exit beam is a fan beam enveloping the detection field (i.e. enveloping the field of view of the photoelectric detector). Exit beam upper and lower marginal rays are indicated on FIG. 4 by dashed lines 49.

In FIG. 4, the collector lens 46 is small and provides an entrance pupil area of the same size as the object-spot 50 on the target-surface 51 in order to optimise depth of view. Provided that the object-spot is correctly focussed onto the pixel 52, the pencil of rays 53 between the object-spot 50 and the entrance pupil (i.e. lens 46) is parallel. As the target-surface 51 moves closer to the sensor, the object-spot 50 gets focussed behind the pixel 52 so that a larger image (that is, a less de-magnified image) of the object-spot is formed. However, the field of view of pixel 51 still contains the full extent of object-spot 50. Light reflected from the surface bordering the object-spot 50 is also focussed behind pixel 52 but is outside its field of view. Thus, the ability of pixel 52 to collect light only from object-spot 50 and not from adjacent parts of the target-surface 51 (that is, the pixel resolution) is maintained for nominally all target-distances less than R, where R is the range at which the target is focussed onto the photo-detector. In other words, the electro-optical sensor of FIG. 4 provides ‘infinite depth of focus’ for target distances between the focal distance R and very close-up distances.

The ‘infinite depth of focus’ feature is especially useful for shadow detection, where the presence of an object such as a flying golf ball is sensed by measuring the blockage of light between a sensor and a retro-reflecting background surface at the focal distance R. For other applications, such as detecting a retro-reflecting target with good resolution over a variable distance of (say) 70% to 100% of R, it is preferable to increase the entrance pupil slightly, and so increase optical gain. In such cases, the entrance pupil dimensions (height and width) may be the same as or up to twice the corresponding dimensions of the object-spot 50.

Rays 54 and 55 illustrate the variation on observation angle pertaining to object-spot 50. Marginal ray 54 exits the projector lens 45 where the lens 45 abuts the upper surface of the substrate 44 close to the substrate front-edge, so as to give the condition for minimum observation angle. Conversely, marginal ray 55 exits the top of the lens 45 to give the condition for maximum observation angle.

Referring now to FIG. 5, an aperture stop 56 is located behind collector lens 57. The lens focuses object-spots 58 and 59 on target surface 60 onto image-spots 58′ and 59′ on a photoelectric detector 61. For clarity of illustration in FIG. 5, a de-magnification ratio (that is, object size to image size) of 2:1 is illustrated, but in practice this ratio is much greater. Dotted line 62 represents the virtual image of aperture 56 as seen at object-spot 58 and also as seen at object-spot 59. In general, all rays from target-surface 60 appear to pass through the ‘window’ marked out by dotted line 62. Thus, the entrance pupil in this case is the image of aperture stop 56 as seen at the target through collector lens 57. To optimise retro-reflective performance, the exit aperture for the co-acting light-emitting source, which can for example be an LED or the image of an LED, should be positioned directly opposite dotted line 62 on the other side of the substrate (not shown). Positioning the aperture in the manner of FIG. 5 changes the angular magnification of the sensor. That is, the angle subtended at the entrance aperture between the two object-spots 58 and 59 is less than the angle subtended at the entrance aperture between the two-image-spots 58′ and 59′.

When the aperture stop 56 is placed further behind lens 57 and on the focal plane of the lens, the lateral demagnification remains 2:1 but the angular magnification is zero. This arrangement is referred to as object-space telecentric.

FIG. 6 shows an example of an entrance pupil being formed by a light-stop aperture 63 placed in front of a collector lens 64. Here, the aperture 63 is placed at the front focal plane of the lens, which results in an image-space telecentric arrangement. Object-spots 65 and 66 are focussed into image-spots 65′ and 66′ with lateral de-magnification of 2.5:1 but the angular magnification is effectively infinite. This arrangement ensures that the light rays incident on the photoelectric detector 67 are all nearly normal to the detector surface. This feature is useful if an interference filter 68 is required to select a narrow spectrum of detected light, since interference filters depend on the transmitted light being at as close to normal incidence for accurate performance.

As before, the exit aperture for the co-acting light-emitting source should be positioned directly opposite dotted line 69 (that is to say, the entrance pupil) on the other side of the substrate (not shown).

In other forms of entrance pupil, two or more apertures can be used. For example, in implementations that use a single large-area photoelectric detector, two elongate apertures parallel to the substrate and positioned on either side of a collector lens can be used to define upper and lower bounds of the exit pupil (measured perpendicular to the substrate), whereas a third aperture defines the width of the entrance pupil (perpendicular to the optic axis) and its position along the optic axis. It is this third aperture that is important since the position of the entrance pupil along the optic axis determines the optimum position of the exit pupil.

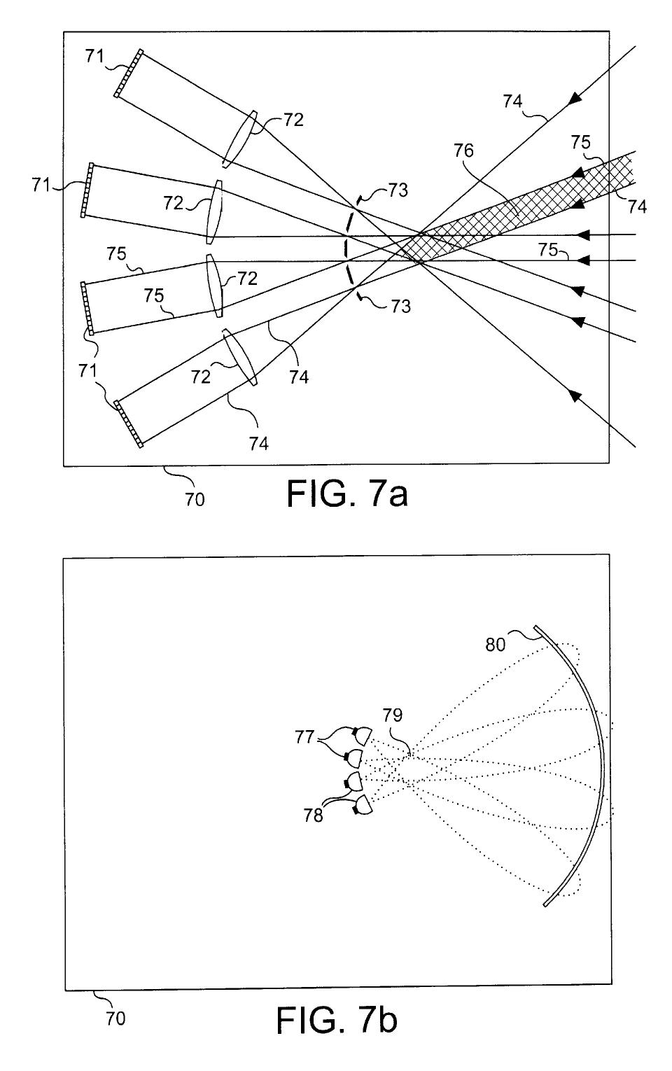

Referring now to FIGS. 7a and 7b, a substrate 70 provides a rigid mounting plane for four distributed linear pixel light-sensing arrays 71 and co-acting collector lenses 72. A four aperture light stop 73 provides four separate entrance pupils, one for each lens and light sensing arrays. The apertures are positioned along each of the four optical axes and on the front focal plane of each lens so as to provide image-space telecentric focussing as described with reference to FIG. 6. The arrangement is such that the lenses 72 are physically separate, as are the light-sensing arrays 71, but the four separate fields of view combine to form one overall field of view that is approximately four times the extent of the individual fields of view.

In order that there are no ‘detection voids’ in the overall field of view, the individual fields of view preferably overlap slightly. Thus, the field of view contained within light rays 74 overlap with the field of view contained within light rays 75. The overlap region is denoted by cross-hatched area 76. We see that this overlap region is substantially parallel so that over a long range, the overlap does not diverge or converge significantly. By this means, the sensor redundancy that occurs in the overlap regions is minimal and can be as small as one or two pixels. Thus, a sensor comprising four 256-pixel arrays can provide at least 1020-pixel resolution over a very wide angle of view.

In the drawing of FIG. 7a, the angle of view of each of the individual sensors is 20 degrees and the combined angle of view is 80 degrees. Combining several small arrays in this manner has several advantages. Although the basic number of lenses is quadrupled, the lenses are small, easy to design, and cheap to produce. By comparison, a lens system that could provide 80 degrees angle of view with an image length four times that of the smaller lenses, would be very complex to design and expensive to produce. Because the angular field of view is very large, image-space telecentric focussing would be very desirable and in some cases mandatory. This in turn would mean that a single lens would have to be four times the length of one of the small, distributed lenses. Advantageously, dividing the sensor overall pixel array length into four quarter-length arrays increases the data capture speed limit by a factor of four. In other embodiments, the individual sensors can have different angles of view and/or different focal lengths to optimise resolution over different parts of an extended target.

FIG. 7b shows the beam-forming arrangement for the projected exit beam. Four LEDs 77 are mounted on suitable heat-sinks (not shown) and are directly attached to radially symmetric collimator lenses 78. The collimator lenses 78 are designed to collect nearly all the emitted light from its attached LED and form a beam that closely follows the law:

Iᵣₑₗ=cos(M×φ) (1)

where Iᵣₑₗ is the light intensity relative to the maximum intensity (i.e. the intensity along the collimator lens axis), M is a magnification factor, φ is the off-axis angle in degrees and −90<M×φ<21 90. When M equals one, Equation (1) becomes the usual cosine 1a w for a Lambertian emitter. As M increases the beam radiant intensity increases but its beam-width decreases. Beam-width is usually expressed as the half-angle width of the beam where Iᵣₑₗ reduces to 0.5. A Lambertian source has half-angle beam width of 60 degrees, whereas a ‘15 degree collimator lens’ reduces the half-angle beam-width to 15 degrees and increases the relative axial light intensity by ideally a factor of four, but coupling and transmission losses reduces this factor slightly.

In the diagram of FIG. 7b, we show the light radiation distributions 79 of the four exit beams by dotted lines. In each beam, the maximum intensity is along the axis of the LED/lens combination and the intensity decreases gradually to zero as the emitted light angles relative to the axis increase. As before, the position of the four exit pupils, which in this case are close to the LEDs, should be positioned directly opposite to a corresponding entrance pupil in aperture stop 73. This minimises the observation angle in respect of each exit pupil and corresponding entrance pupil but light from adjacent exit pupils also contribute to the retro-reflective performance. Provided that the spacing between adjacent exit pupils is small compared to the target range R, the increase in minimum observation angle can be negligible.

For example, in a long range application, R is 20 metres, the substrate thickness T is 6.35 millimetres (0.25 inch) to provide high rigidity and stability and the spacing between adjacent exit pupils (and therefore between adjacent entrance pupils) is 15 millimetres. The minimum observation angle pertaining to corresponding exit and entrance pupil pairs is thus less than 0.02 degree whereas the minimum observation angle for retro-reflection between adjacent but not directly opposite exit and entrance pupils is still less than 0.05 degree. This small increase in observation angle will have only a slight effect on the sensor sensitivity. If necessary, the alignment of individual exit beams can be adjusted to provide more light intensity in ‘cross-over’ regions where light sharing occurs.

The collimator lenses 78 only partly collimate the exit beams and produce beams that are radially symmetric about their optical axes. A circular Fresnel lens 80 provides additional lens power in every plane normal to the substrate within the sensor angular field of view. Lens 80 is equivalent to a cylindrical lens with power in the meridonial plane normal to the substrate but instead of its length axis being straight and parallel to the substrate, the axis is curved and parallel to the substrate. This provides final focussing of the four exit beams to generate a composite fan beam that is highly collimated normal to the substrate but diverges in a wide angle parallel to the substrate.

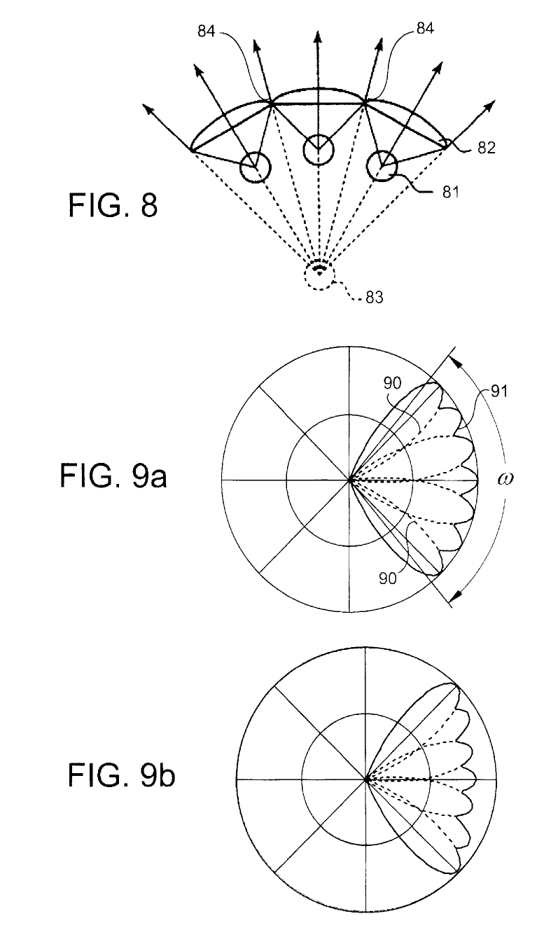

An important property of beams that have radiation characteristics obeying Equation (1) or closely similar, is that they can be combined to provide a composite beam that does not exhibit abrupt changes in light intensity. In this respect, it is instructive to consider FIG. 8 which is a schematic diagram of beam forming optics according to prior art (notably FIG. 2(b)) of U.S. Pat. No. 6,362,468 of Murakami et al. In FIG. 8 of the present invention, the light from three LED devices 81 are focussed by three lenses 82 to form virtual images such that a composite wide-angle light beam is formed with apparent source at 83. However, at the junctions 84 between adjacent lenses, the beam-forming is discontinuous and abrupt changes occur. These abrupt changes are unavoidable due to the finite size of the light sources, lens rim reflections, impractical alignment requirements and other effects. However, in sensors according to the invention, it is preferable that the overall exit beam light intensity does not exhibit abrupt changes as this markedly degrades the sensor performance. This is particularly the case where the sensor is used to determine small changes in individual pixel outputs to determine the edge position of a retro-reflective surface.

It is thus preferable that the light intensity fall-off characteristic at overlapping edges of adjacent beams is gradual. Two or more beams can then be combined to form a wider composite beam where the light intensity changes gradually throughout the composite beam. In one exemplary embodiment according to the invention, four LEDs (such as sold under the Registered Trade Mark OSRAM as type SFH4230) are used in conjunction with 15 degree collimator lenses such as part No. 124 from Polymer Optics Limited. The output beam from the 15 degree collimator lens closely approximates the radiation distribution of Equation (1) with M equal to 4 and beam half-width of 15 degrees. The LEDs and attached 15 degree collimator lenses are mounted such that their axes are aligned at 30 degree intervals. FIG. 9a shows the resulting radiation patterns, where dashed traces 90 correspond to the four individual beams, and solid trace 91 shows the characteristic of the combined beam, which extends over an angular field of view w of about 100 degrees. Although the overall radiation characteristic 91 exhibits peak to peak ripple of about 14%, the maximum percentage change per angular degree is very much smaller than 14%. Furthermore, assuming that there are about 10 pixels per degree in the sensor angular field of view, the percentage change in light intensity between adjacent pixels is negligible and certainly less than 1% per degree.

FIG. 9b shows a modified radiation characteristic for the composite beam where the intensity amplitudes of the two central contributing beams are reduced to 85% of the outer beams. This provides more light intensity at angular extremities of the composite beam. This may be required to compensate for loss of gain because the target surface is further from the sensor at these extremes and the ‘entrance angles’ are greater. The ‘entrance angle’ in retro-reflectors is the angle of incidence of light measured with respect to the normal to the retro-reflector surface. The coefficient of retro-reflection is usually a maximum at normal light incidence (that is, zero entrance angle) and falls off at high entrance angle.

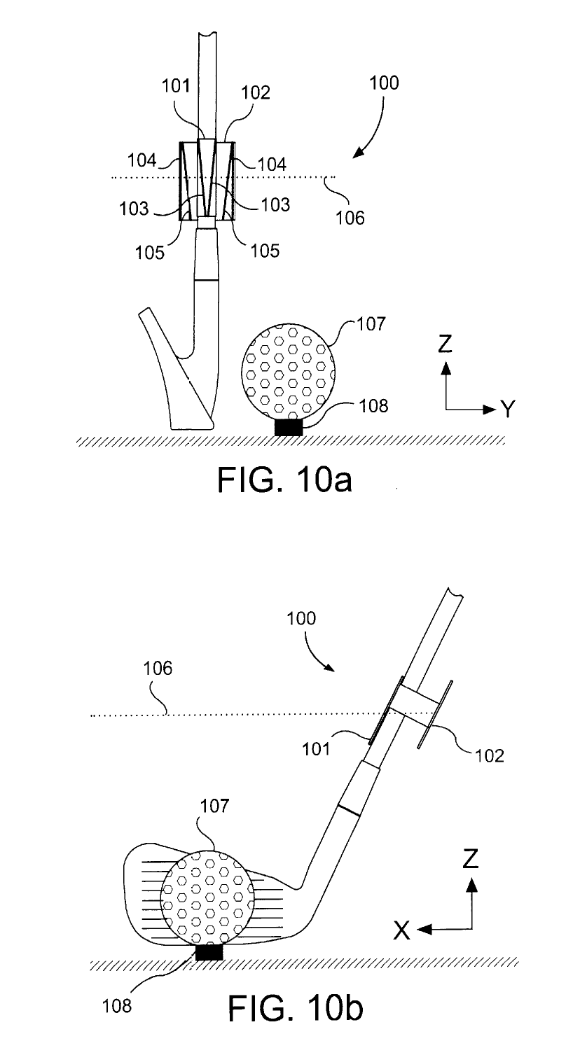

FIGS. 10a and 10b show toe-end and impact-face views respectively, of a golf club-head 100 with a retro-reflective shaft attachment. The shaft attachment comprises a front plate 101 and a rear plate 102. The attachment can be used in conjunction with the sensor of FIG. 1 to measure the club swing parameters prior to impact with a golf ball. Knowing the pre-impact, swing parameters and the subsequent ball launch velocity components (as measured by the arrangement of FIGS. 10a and 10b), the spin components of the ball (that is, spin rate and spin axis) can be determined. This information is useful for diagnosis of the golf shot identification process and provides valuable additional information for golfers using the facility.

The major axes of the front plate 101 and rear plate 102 are both parallel to the shaft axis and their minor axes are parallel to a plane that is nominally perpendicular to the impact face. The front plate 101 is provided with two reflecting strips 103 that are nominally symmetrically-located with respect to the shaft axis and mutually inclined such that they are close together at the bottom of the plate and diverge towards the top. The rear plate 102 is provided with two pairs of reflecting strips each comprising an outer strip 104 that is nominally parallel to the shaft axis and an inner reflecting strip 105 that is inclined to the outer strip such that they are close together at the top of the plate and diverge towards the bottom. The reflecting strips 103, 104 and 105 are all straight and retro-reflecting with, preferably, uniform and equal widths in the range 0.5 to 2.0 millimetre.

A sensor device (not shown) senses reflections from all six reflecting strips and the pattern of the sensed reflections provide measurements of the six degrees of freedom of the retro-reflective shaft attachment; the six degrees of freedom are: X, Y and Z displacements, and roll, pitch and yaw rotations. The detection device is preferably a linear pixel array combined with a light source and optics to optimise retro-reflective performance as described above with reference to FIG. 1. The detection plane beam from this sensor is horizontal and depicted in FIGS. 10a and 10b by dotted lines 106. In an alternative arrangement, the beam is inclined so as to be approximately perpendicular to the shaft.

When the club-head 100 is square to the intended line of impact and the club shaft lies in a vertical plane, then the sensed reflection pattern is symmetrical. Vertical upward movement causes the angular spacing between the front-plate reflectors 103 to diverge and that between the rear-plate adjacent reflectors 105 to converge and vice versa. The reflections from the outer reflectors 104, being parallel, do not change for vertical movements of the shaft but their pixel separation is inversely proportional to the distance of the shaft from the sensor and thus gives a measure of heel-toe impact offset. Movement along the Y-axis is detected by an overall shift in the pixel positions. Yaw rotation (which primarily affects clubface angle) can be detected by lateral parallax movement of the front plate 101 relative to the back plate 102. Pitch rotation (which primarily affects dynamic lie) is detected by vertical parallax. Roll rotation (lofting or de-lofting) causes asymmetry in the pixel spacing of the two outermost pairs of reflectors.

Other forms of retro-reflecting attachments may be provided. For example, the six line elements (103 to 105) can be replaced by three elongate triangles (that is, the retro-reflecting surfaces extend within the spaces between the three line pairs); in this configuration, two edges of each triangle are sensed. The retro-reflecting pattern may be a ‘reverse video’ form of either of the above arrangements (lines or triangles), and in either case the lines or triangles may be formed by a mask laid over a uniform retro-reflecting background.

The essential attributes of the arrangement of reflectors are that there is sufficient width, height and depth to provide the necessary measurement-sensitivity while preferably being compact and light-weight. The reflective pattern may be hidden from view behind infrared filter material and can be fabricated from retro-reflective sheeting or moulded or otherwise formed into the rears of the plates 101, 102. Supplementary reflective strips may be attached directly onto the shaft or parts of the club-head to provide ‘out of position’ indicators. Specially designed elongate surface lens elements may be provided to focus incident light onto the edge or strip of retro-reflective element in order to enhance system gain and precision.

The optical detection of an edge as involved above is not a diffraction-limited process. The ability of a system to resolve two closely-adjacent spots or lines is limited by diffraction.

Prototype versions of the electro-optical sensor of FIG. 1 demonstrate very high signal to noise ratio such that extremely small increments of movement are detectible. Thus, although the pixel resolution may be of the order of one millimetre, very small changes of the order of a few microns can be detected from changes in the greyscale level of adjacent pixels. It is thus evident that a limitation on the accuracy of the system is likely to be the accuracy of the reflective pattern, and in particular the straightness of edges.

The reflective pattern may be formed from glass bead retro-reflective tape, where the glass-bead diameter is a few microns. Alternatively, the pattern lines may be provided as precisely fabricated grooves with glass-bead filler. This can give uniform edges of retro-reflection whereas micro-prismatic tape, where the micro-prisms are greater than 0.1 millimetre, would have ragged reflective edges unless the micro-prisms are aligned exactly and uniformly along an edge. Custom-made micro-prism reflectors can be provided to meet the special requirements of the invention.

Electro-optical sensors for responding to movement of the golf club head 100 of FIGS. 10a and 10b, may be located in the known areas where the golf ball 107 is struck (for example, as illustrated, in the locality of golf tee 108). The detection plane 106 can then be best positioned to detect the six reflectors 103, 104 and 105 as the club-head 100 approaches the ball 107, even if the club-head 100 is offset from the ideal central impact position.

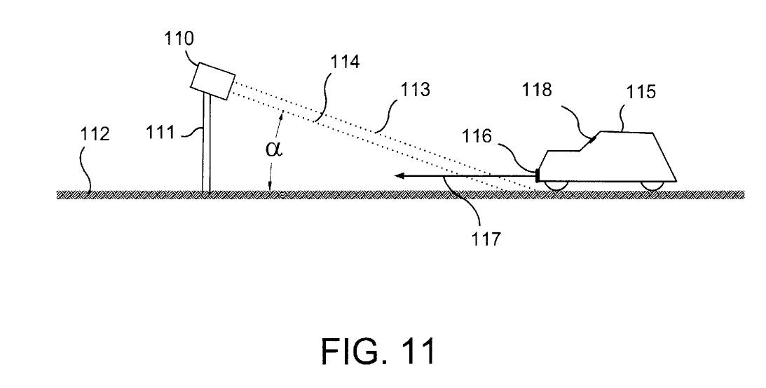

Referring now to FIG. 11, a sensor housing 110 is mounted on a support pillar 111 at a suitable height above a road surface 112. The sensor housing 110 contains two electro-optical sensors according to FIGS. 1a, 1b and 1c having detection planes 113 and 114 respectively, each normal to the plane of FIG. 11 and inclined at an angle α relative to the road surface 112. A vehicle 115 (shown in outline) travels towards the sensor housing 110 and support pillar 111, and its vehicle registration number plate 116 passes first through detection plane 113 and then detection plane 114. The vehicle registration number plate 116 comprises a retro-reflecting back-plate with non-reflecting alphanumeric characters superimposed. The sensors, which may use distributed linear pixel arrays as illustrated in FIG. 7a, acquire data at high speed so that a composite image of the alphanumeric characters on the number plate 116 can be obtained by combining several line scans of the plate 116 as it passes through the detection planes 113 and 114. The speed of the vehicle can be determined from the time delay of the retro-reflections in detection plane 114 relative to the corresponding reflections in detection plane 113.

By way of example, the vehicle may be travelling at 40 metres per second (90 miles per hour) and the sensors each complete a line scan every 100 microseconds. The vehicle will thus travel 4 millimetres between each line scan in the direction indicated by arrow 117, but because the detection planes are inclined at angle θ to arrow 117 the incremental line scans on the number plate 116 will occur at (4 millimetre)×tan(θ). Typically θ is in the range 15 to 30 degrees, so the resolution between successive lines can be of the order of 2 millimetre or less. A similar resolution along the line scan (that is, in approximate horizontal direction across the number plate 116) is easily achieved with distributed linear pixel arrays as described previously.

At lower speeds, the number of lines in the composite image increases in inverse proportion to the speed of the vehicle in the direction of arrow 117. For medium or low vehicle speeds, it is preferable to combine adjacent line scans (by adding successive line-scan data) in groups of two, three, four, or more as the vehicle speed (determined by the time delay) decreases. In this manner, the volume of data required for image analysis is controlled.

In an alternative embodiment, detection plane 113 uses a small number of non-integrating, large area photoelectric detectors, which have much faster signal response time compared with pixel arrays but have limited resolution. This detection plane is used for high speed detection of a number plate just before it enters the field of view of detection plane 114 and also to measure the approximate position of the number plate 116 in the field of view, but does not have the capability of detecting the alphanumeric characters on the number plate. This in turn provides a means of activating the high resolution detection plane 114 and optionally selectively enabling only those parts of the distributed pixel arrays that are required to capture the number plate data. This procedure greatly improves the data capture efficiency. As before, the speed of the vehicle can be determined from the time delay between the signal responses in the two detection planes.

In addition to sensing the pattern on a number plate, the electro-optical sensors may also detect and decode retro-reflective data such as a matrix code on a vehicle windscreen. This retro-reflective code may be provided on a periodically renewable device 118 such as a tax-disc or may be a permanent in-built part of the windscreen to supplement the normal number plate. The code-containing device may be attached to the inside of the vehicle-windscreen using optically transparent cement or the like with matching refractive index to enhance performance. Preferably, the retro-reflective surface should be optimised to operate at the most likely entry angle for a given vehicle and sensor arrangement.

Advantageously, the windscreen retro-reflective data can be positioned on that part of the windscreen that is cleaned by wipers, but not obstructing the driver's view, for example, in the area behind the rear-view mirror or at another edge of the wiper-sweep remote from the driver's main view of the road. Preferably, any retro-reflective data that may be obstructed by a wiper is duplicated in either an adjoining or separate position of the windscreen so that one or other instances of the data is always in view of the sensors. When a wiper blade does obstruct part of the code-bearing device, its presence and position can be determined from the shadow it creates on the retro-reflective background of the device.

1-14. (canceled)

15. An electro-optical sensor comprising:
(a) light-transmitting means, the light-transmitting means comprising a light-emitter and light-projection optics co-acting with the light-emitter for projecting a light beam from the light-emitting means to illuminate a retro-reflective target at a target-location spaced from the electro-optical sensor, the light-projection optics having a light-exit pupil viewed from the target-location ;
(b) light-receiving means, the light-receiving means comprising a photoelectric detector and light-collection optics co-acting with the photoelectric detector for focusing onto the photoelectric detector light reflected retro-reflectively from the target-location, the light-collection optics having a light-entrance pupil viewed from the target-location;
(c) light-screening means defining end-edges on opposite sides respectively of the light-screening means; and
(d) means locating the light-transmitting means and the light-receiving means alongside one another; and
(e) means locating the light-screening means between the light-transmitting means and the light-receiving means, the light-screening means intervening between the light-transmitting means and the light-receiving means to screen from the light-receiving means light projected from the light-transmitting means;
wherein said light-exit pupil of the light-projection optics and said light-entrance pupil of the light-collection optics abut respectively the end-edges on opposite sides of the light-screening means.

16. The electro-optical sensor according to claim 15, wherein the entrance pupil of the light-collection optics has a height measured normal to the light-screening means, and the end-edges of the light-screening means are separated from one another by a separation distance less than said height of the light-entrance pupil.

17. The electro-optical sensor according to claim 16, wherein the separation distance is less than 20% of said height of the light-entrance pupil.

18. The electro-optical sensor according to claim 15, wherein the photoelectric detector is a linear pixel array.

19. The electro-optical sensor according to claim 18, wherein the light beam projected from light-emitting means has an incremental beam-intensity variation, the light-receiving means has a light-detection field defined in pixels, and the incremental beam-intensity variation is no more than 10% over any increment of ten pixels in the light-detection field.

20. The electro-optical sensor according to claim 19 wherein the incremental beam-intensity variation of the light beam projected from the light-emitting means, is no more than 1% as between consecutive pixels in the light-detection field.

21. The electro-optical sensor according to claim 15, wherein the light-entrance pupil of the light-collection optics has a center, the light-collection optics has an optical axis, and the center of the entrance pupil of the light-collection optics is located between the light-screening means and the optical axis of the light-collection optics.

22. The electro-optical sensor according to claim 21, wherein the light-entrance pupil of the light-collection optics extends to less than 50% of the spacing of the optical axis of the light-collection optics from the light-screening means.

23. The electro-optical sensor according to claim 15, wherein the light-entrance pupil of the light-collection optics is smaller than the light-exit pupil of the light-projection optics.

24. The electro-optical sensor according to claim 15, wherein the light-receiving means has a light-detection field and a minimum observation angle, and wherein the minimum observation angle is less than 0.2 degree throughout the light-detection field.

25. The electro-optical sensor according to claim 24, wherein the minimum observation angle is less than 0.05 degree throughout the light-detection field.

26. The electro-optical sensor according to claim 15, wherein the light-entrance pupil of the light-collection optics has dimensions which are one of the same as and up to twice dimensions of a pixel of the photoelectric detector when viewed in the entrance pupil of the light-collection optics from the target-location.

27. The electro-optical sensor according to claim 15, wherein the light-screening means comprises a substrate member having first and second sides opposite one another through the substrate member, means mounting the light-transmitting means on the first of the opposite sides of the substrate member, and means mounting the light-receiving means on the second of the opposite sides of the substrate member.

28. The electro-optical sensor according to claim 15, wherein the end-edges on opposite sides respectively of the light-screening means are parallel straight edges of the light-screening means.

29. The electro-optical sensor according to claim 15, comprising a plurality of light-emitters that have individually co-acting light-projection optics for projecting a plurality of light beams that merge with one another, and photoelectric detectors having individually co-acting light-collection optics with fields of view that merge with one another.

30. A method of electro-optical sensing comprising:
(a) a step of projecting a light beam from a light-emitter via co-acting light-projection optics to illuminate a retro-reflective target at a target-location spaced from the light-projection optics, the light-projection optics having a light-exit pupil viewed from the target-location;
(b) a step of responding to light received by a photoelectric detector via co-acting light-collection optics from the retro-reflective target at the target-location, the light-collection optics having a light-entrance pupil viewed from the target-location;
(c) a step of mounting the light-emitter and the co-acting light-projection optics on a first of two opposite sides of a substrate; and
(d) a step of mounting the photoelectric detector and the co-acting light-collecting optics on the second of the two opposite sides of the substrate to screen the photoelectric detector and the co-acting light-collecting optics from the light-emitter and the co-acting light-projection optics;
wherein said light-exit pupil of the light-projection optics and said light-entrance pupil of the light-collection optics abut respectively end-edges of the two opposite sides of the substrate.

31. The method according to claim 30, wherein the entrance pupil of the light-collection optics has a height measured normal to the substrate, and the end-edges of the substrate are separated from one another by a separation distance less than said height of the light-entrance pupil.

32. The method according to claim 31, wherein the separation distance is less than 20% of said height of the light-entrance pupil.

33. The method according to claim 30, wherein the photoelectric detector is a linear pixel array.

34. The method according to claim 30, wherein the light-entrance pupil of the light-collection optics has a center, the light-collection optics has an optical axis, and the center of the entrance pupil of the light-collection optics is located between the light-screening means and the optical axis of the light-collection optics.
